(19) United States
(12) Patent Application Publication
(10) Pub. No.: US 2002/0180018 A1
(43) Pub. Date: Dec. 5, 2002

(54) Leadframe locking structures and method therefor

(76) Inventor: Charles A. Shermer, Chandler, AZ (US)

Correspondence Address: WEISS & MOY PC, 4204 NORTH BROWN AVENUE, SCOTTSDALE, AZ, 85251, US

(21) Appl. No.: 09/867,998

(22) Filed: May 29, 2001

(51) Int. Cl. H01L 23/02

(52) U.S. Cl. 257/679

(57) ABSTRACT

A semiconductor assembly and method has channels formed in a leadframe. The channels act as a lock between the leadframe and a mold compound when the mold compound flows into the channels and congeals during the encapsulation process. The semiconductor assembly and method may further have a plurality of raised areas on the leadframe which are used for wirebonds. The raised areas allow the mold compound to get underneath the wirebonds and capture the wirebonds when the mold compound congeals during the encapsulation process.

### FIELD OF THE INVENTION

This invention relates to semiconductor packages and, more specifically, to leadframe locking structures that will promote adhesion of the mold compound to the die flag area of the leadframe and improve downbond reliability.

### BACKGROUND OF THE INVENTION

Integrated circuit packages generally consist of an integrated circuit chip which is physically attached to a leadframe by some type of adhesive. The integrated circuit chip is then electrically interconnected to the leadframe and to input-output leads. An encapsulating material (i.e., molding compound) is then placed over the assembly (i.e., the integrated circuit chip, the leadframe and the interconnects). The molding compound is used to seal and protect the circuitry from the environment.

The reliability of integrated circuit packages has greatly increased from when they were first produced. This is due largely to improved encapsulating materials, die passivation, and manufacturing processes. However, delamination still remains a problem. Delamination is the splitting apart or separation of layers in the integrated circuit package. Generally, delamination will occur at interfaces between the molding compound and the die or the leadframe. One reason for delamination is that the mold compound does not adhere well to silver or nickel palladium electroplating which is commonly used to facilitate down and groundbonds in integrated circuit packages. Delamination generally occurs during reliability stress testing. Delamination can be particularly catastrophic when delamination occurs between the die pad and the mold compound and wire bonds are placed in the die pad area.

Therefore, a need existed to provide a leadframe locking structure and method that will promote adhesion of the mold compound to the die flag area of the leadframe.

### SUMMARY OF THE INVENTION

A semiconductor assembly and method has channels formed in a leadframe. The channels act as a lock between the leadframe and a mold compound when the mold compound flows into the channels and congeals during the encapsulation process. The semiconductor assembly and method may further have a plurality of raised areas on the leadframe which are used for wirebonds. The raised areas allow the mold compound to get underneath the wirebonds and capture the wirebonds.

### BRIEF DESCRIPTION OF THE DRAWINGS

FIG. 1 is a top view of an embodiment of a leadframe having the locking structure of the present invention;

FIG. 1A is an exploded cross-sectional side view of an embodiment of the locking structure used in the leadframe depicted in FIG. 1;

FIG. 1B is an exploded cross-sectional side view of another embodiment of the locking structure used in the leadframe depicted in FIG. 1;

FIG. 2 is a top view of another embodiment of a leadframe having the locking structure of the present invention;

FIG. 2A is an exploded cross-sectional side view of an embodiment of the locking structure used in the leadframe depicted in FIG. 2;

FIG. 2B is an exploded cross-sectional side view of another embodiment of the locking structure used in the leadframe depicted in FIG. 2;

FIG. 3 is a top view of another embodiment of a leadframe having the locking structure of the present invention;

FIG. 3A is an exploded cross-sectional side view of an embodiment of the locking structure used in the leadframe depicted in FIG. 3;

FIG. 3B is an exploded cross-sectional side view of another embodiment of the locking structure used in the leadframe depicted in FIG. 3;

FIG. 4 is a top view of another embodiment of a leadframe having the locking structure of the present invention; and

FIG. 4A is an exploded cross-sectional side view of an embodiment of the locking structure used in the leadframe depicted in FIG. 4.

The novel features believed characteristic of the invention are set forth in the appended claims. The invention itself, as well as a preferred mode of use, and advantages thereof, will best be understood by reference to the following detailed description of illustrated embodiment when read in conjunction with the accompanying drawings, wherein like reference numerals and symbols represent like elements.

### DETAILED DESCRIPTION

Leadframes are manufactured by either progressive sheet metal stamping or chemical etching. Stamping is a highly automated and high speed process. Typically, sheet metal, in roll form, is pierced along both edges to create indexing holes that help align the sheet metal during processing. The location holes are used to advance the sheet metal through a stamping machine. The stamping machine will generally have a plurality of die and punch sets. As the sheet metal is advanced through the stamping machine, the die and punch sets will perform a series of stampings that progressively approach the final leadframe geometry.

Chemical etching is the more widely used method for manufacturing leadframes. Chemical etching may be done either in a continuous reel-to-reel form or in flat sheets. Both processes generally have similar steps. Both sides of the lead frame are coated with an etching material with the help of a photoresist film. Next, the preclean and activation steps are preformed followed by lamination. The photoresist is then exposed to the required leadframe pattern with the aid of an ultraviolet source and a precision pattern glass. The areas to be retained as metals are coated with resists and the etched parts are kept free of the resist in the finished pattern. The final steps include running past the material through a series of nozzles spraying etchant, after which the protective photoresist film is stripped from the finished leadframe. The final etched leadframes are collected on reels or in unit-cut lengths.

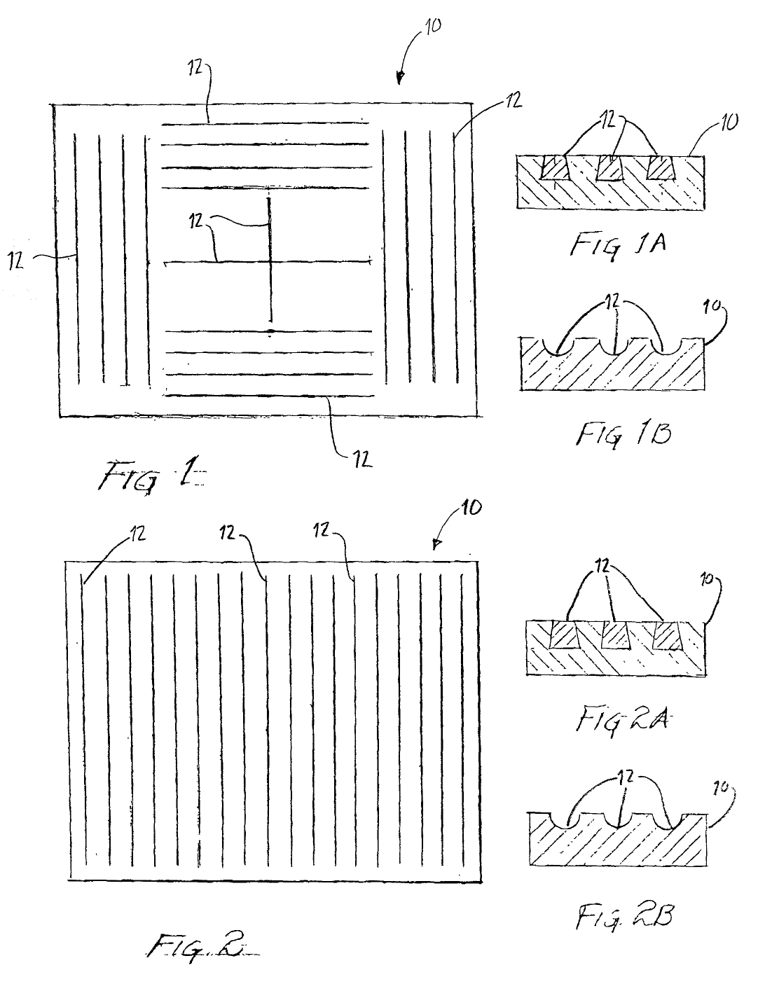

Referring now to FIG. 1, a leadframe having a die flag area 10 (hereinafter die flag 10) is shown. The leadframe and hence the die flag 10 may be manufactured by either progressive sheet metal stamping or chemical etching. The die flag 10 has a plurality of channels 12 which are formed in the die flag 10. The channels 12 may be formed in the die flag 10 during any step of the manufacturing process of the leadframe. The channels 12 may be formed by either a stamping process or by chemical etching. Further, the channels 12 may be formed on the leadframe either before or after silver spot plating of the leadframe.

In the embodiment depicted in FIG. 1, the channels 12 are arranged in a pattern so that channels 12 are formed on each side of the die flag 10. A plurality of channels 12 are formed along each side of the die flag 10 and run approximately parallel to the respective side. A pair of channels 12 are also located in a central area of the die flag 10. The pair of channels 12 intersect one another in the center of the die flag 10. FIG. 1 shows four (4) channels 12 are formed along each side of the die flag 10. However, this is shown only as an example and should not be seen as to limit the scope of the present invention.

The channels 12 allow the mold compound to adhere better to the die flag 10 when the leadframe is encapsulated. During the encapsulation process, a mold compound will be poured onto the leadframe. The mold compound will flow into the channels 12. When the mold compound begins to congeal, the channels 12 will allow the mold compound to adhere better to the die flag 10. The channels 12 will allow a physical lock to form between the mold compound and the die flag 10. This will help in preventing delamination of the integrated circuit package.

It should be noted that while FIG. 1 shows the channels 12 on the die flag 10, the channels 12 may be placed anywhere on the surface of the leadframe. The channels 12 may be placed on any area on the leadframe where better adhesion is required between the =mold compound and the metal part of the leadframe. The channels 12 may further be used on the leadfinger areas of the leadframe to promote leadfinger locking. The channels 12 may also be placed on one or both sided of the leadframe.

Referring now to FIG. 1A, one embodiment of the channel 12 is shown. In this embodiment, the channel 12 takes the shape of an open triangle or trapezoid. The channels 12 in FIG. 1A are formed by a striking and coining process. During the manufacturing of the leadframe, the leadframe will be run through a stamping machine. The stamping machine will have a punch and die set which will strike the leadframe forming the channels 12. When the stamping machine strikes the leadframe to form the channels 12, a slight build-up will form around the opening of the channel 12. A press may be used to flatten the build-up there by partially closing the opening as shown in FIG. 1A.

Referring now to FIG. 1B, another embodiment of the channel 12 is shown. In this embodiment, the channel 12 takes the shape of a semicircle or “U” shape. The channels 12 in FIG. 1B are formed by an etching process. The etching of the channels 12 may be before or after silver plate. If the channels 12 are etched into the die flag 10 after silver plate, the etching process will etch the silver away. This will expose the copper which will further increase the adhesion between the mold compound and the die flag 10. This is due to the fact that the mold compound does not adhere well to silver or nickel palladium electroplating.

Referring now to FIG. 2, another leadframe having a die flag 10 is shown. This embodiment is similar to the embodiment depicted in FIG. 1. The leadframe and the channels 12 could be made in the same manner as discussed above for the embodiment shown in FIG. 1. The main difference between the embodiments is the pattern formed by the channels 12. In the embodiment depicted in FIG. 2, all the channels 12 run parallel to one another. The channels 12 shown in FIG. 2 run in a vertical manner along the length of the die flag 10. However, the channels 12 could also run in a horizontal manner along the width of the die flag 10. It should be noted again, that the pattern of the channels 12 are just examples and should not be seen as to limit the scope of the present invention.

As with FIG. 1, FIG. 2 shows the channels 12 on the die flag 10. However, the channels 12 may be placed anywhere on the surface of the leadframe. The channels 12 may be placed on any area on the leadframe where better adhesion is required between the mold compound and the metal part of the leadframe. The channels 12 may further be used on the leadfinger areas of the leadframe to promote leadfinger locking. The channels 12 may also be placed on one or both sided of the leadframe.

The channels 12 in FIG. 2 will be similar to those shown in FIGS. 1A and 1B. Referring now to FIG. 2A, one embodiment of the channel 12 for the embodiment depicted in FIG. 2 is shown. In this embodiment, the channel 12 takes the shape of an open triangle or trapezoid. The channels 12 in FIG. 2A are formed by a striking and coining process similar to that discussed above. During the manufacturing of the leadframe, the leadframe will be run through a stamping machine. The stamping machine will have a punch and die set which will strike the leadframe forming the channels 12. When the stamping machine strikes the leadframe to form the channels 12, a slight build-up will form around the opening of the channel 12. A press may be used to flatten the build-up there by partially closing the opening as shown in FIG. 2A.

Referring now to FIG. 2B, another embodiment of the channel 12 for the embodiment depicted in FIG. 2 is shown. In this embodiment, the channel 12 takes the shape of a semicircle or “U” shape. The channels 12 in FIG. 2B are formed by an etching process. The etching of the channels 12 may be before or after silver plate. If the channels 12 are etched into the die flag 10 after silver plate, the etching process will etch the silver away. This will expose the copper which will further increase the adhesion between the mold compound and the die flag 10. This is due to the fact that the mold compound does not adhere well to silver or nickel palladium electroplating.

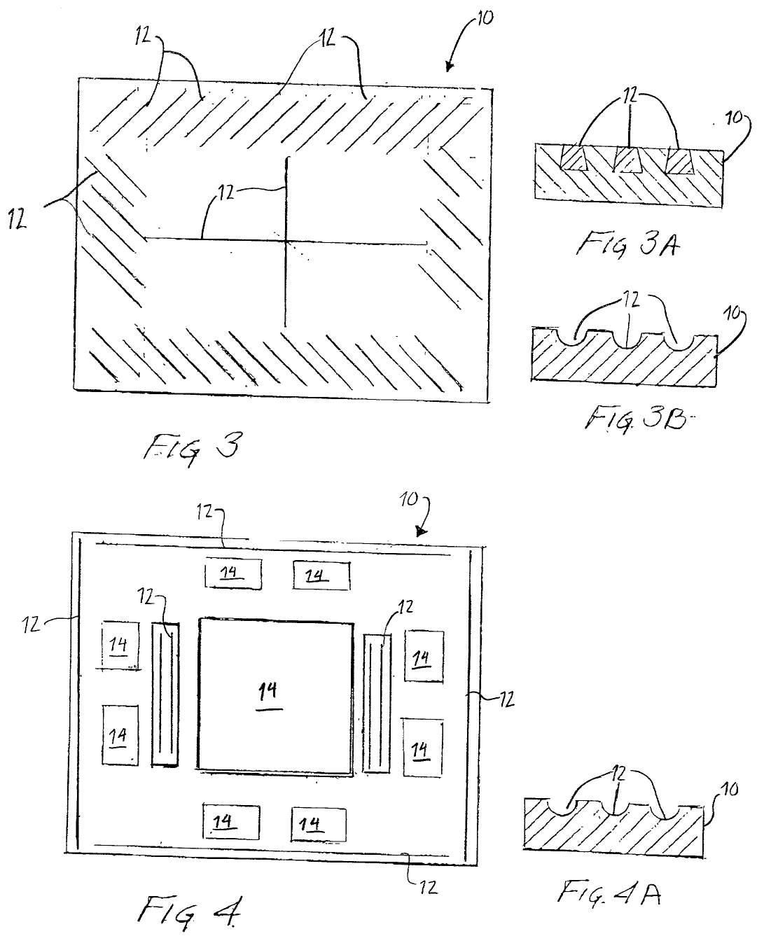

Referring now to FIG. 3, another leadframe having a die flag 10 is shown. This embodiment is similar to the previous embodiments depicted in FIGS. 1 and 2. The leadframe and the channels 12 could be made in the same manner as discussed above for the embodiments shown in FIG. 1 and FIG. 2. Again, the main difference between the embodiments is the pattern formed by the channels 12. In the embodiment depicted in FIG. 3, a majority of the channels 12 run at a slant. The channels 12 run at a slant along the outer perimeter of the die flag 10. A pair of channels 12 are also located in a central area of the die flag 10. The pair of channels 12 intersect one another in the center of the die flag 10. Again, it should be noted that the pattern of the channels 12 are just examples, and should not be seen as to limit the scope of the present invention.

The channels 12 in FIG. 3 will be similar to those shown in FIGS. 1A-1B and 2A-2B. Referring now to FIG. 3A, one embodiment of the channel 12 for the embodiment depicted in FIG. 3 is shown. In this embodiment, the channel 12 takes the shape of an open triangle or trapezoid. The channels 12 in FIG. 3A are formed by a striking and coining process similar to that discussed above. During the manufacturing of the leadframe, the leadframe will be run through a stamping machine. The stamping machine will have a punch and die set which will strike the leadframe forming the channels 12. When the stamping machine strikes the leadframe to form the channels 12, a slight build-up will form around the opening of the channel 12. A press will then be used to flatten the build-up there by partially closing the opening as shown in FIG. 3A.

Referring now to FIG. 3B, another embodiment of the channel 12 for the embodiment depicted in FIG. 3 is shown. In this embodiment, the channel 12 takes the shape of a semicircle or “U” shape. The channels 12 in FIG. 3B are formed by an etching process. The etching of the channels 12 may be before or after silver plate. If the channels 12 are etched into the die flag 10 after silver plate, the etching process will etch the silver away. This will expose the copper which will further increase the adhesion between the mold compound and the die flag 10. This is due to the fact that the mold compound does not adhere well to silver or nickel palladium electroplating.

Referring now to FIG. 4, another leadframe having a die flag 10 is shown. The embodiment depicted in FIG. 4 is an etched version. The die flag 10 is half etched so that the die flag 10 has a plurality of raised sections 14. A centrally located raised section 14A is generally where the die would be attached to the die flag 10. The die is generally attached by a polymer adhesive. The polymer adhesive may have some type of additive to make the polymer adhesive more thermally conductive. The die is further attached to leads by a wirebonding process. This will allow electrical continuity between the die and external terminals. A second raised areas 14B along the outer edges of the die flag 10 are used for downbonds and/or ground bonds (hereinafter downbonds) for the die. The downbonds are placed on the raised areas 14B for reliability reasons. The raised sections will allow the mold compound to get underneath the bonds and capture it. The reason most bonds fail is that the mold compound delaminates from the surface of the die flag 10. If the downbonds are co-planer with the surface of the die flag 10, the downbonds and the delamination interface at the same point. By placing the downbonds on the raised sections 14B, this will change the interface of the downbond up and away from the delamination thereby increasing the reliability of the downbond.

The die flag 10 further has channels 12 located around the outer perimeter of the die flag 10. Channels 12 may further be located on each side of the centrally located raised section 14. As with the previous embodiments, the channels 12 allow the mold compound to adhere better to the die flag 10 when the leadframe is encapsulated. The channels 12 may be placed anywhere on the surface of the leadframe. The channels 12 may be placed on any area on the leadframe where better adhesion is required between the mold compound and the metal part of the leadframe. The channels 12 may also be placed on one or both sided of the leadframe.

Referring to FIG. 4A, one embodiment of the channel 12 for the embodiment depicted in FIG. 4 is shown. In this embodiment, the channel 12 takes the shape of a semicircle or “U” shape. The channels 12 in FIG. 4A are formed by an etching process. The etching of the channels 12 may be before or after silver plate. If the channels 12 are etched into the die flag 10 after silver plate, the etching process will etch the silver away. This will expose the copper which will further increase the adhesion between the mold compound and the die flag 10. This is due to the fact that the mold compound does not adhere well to silver or nickel palladium electroplating.

The above description of embodiments of the present invention is intended to be illustrative and not limiting. Other embodiments of this invention will be obvious to those skilled in the art in view of the above disclosure and fall within the scope of the present invention.

What is claimed is:

1. A semiconductor assembly, comprising:
a leadframe;
a die coupled to the leadframe;
at least one channel formed in a top surface of the leadframe; and
a mold compound for encapsulating the semiconductor assembly wherein the mold compound flows into the at least one channel and bonds with the at least one channel forming a lock between the mold compound and the leadframe.

2. The semiconductor assembly in accordance with claim 1 further comprising:
a first raised area on the leadframe where the die is coupled; and
a plurality of second raised areas on the leadframe used for wirebonds wherein the plurality of second raised areas allow the mold compound to get underneath the wirebonds and capture the wirebonds.

3. The semiconductor assembly in accordance with claim 1 further comprising a plurality of channels formed in the top surface of the leadframe.

4. The semiconductor assembly in accordance with claim 1 wherein the at least one channel is triangular in shape.

5. The semiconductor assembly in accordance with claim 1 wherein the at least one channel is “U” shaped.

6. The semiconductor assembly in accordance with claim 4 wherein the at least channel is formed by stamping and coining the leadframe.

7. The semiconductor assembly in accordance with claim 5 wherein the at least channel is formed by etching the leadframe.

8. A mounting for a semiconductor package, comprising:
a leadframe; and
at least one channel formed in a top surface of the leadframe.

9. The mounting for a semiconductor package in accordance with claim 8 wherein the at least one channel forms a lock between the leadframe and a mold compound which flows into the at least one channel.

10. The mounting for a semiconductor package in accordance with claim 8 further comprising:
a first raised area on the leadframe forming a die pad; and
a plurality of second raised areas on the leadframe used for wirebonds wherein the plurality of second raised areas allow a mold compound to get underneath the wirebonds and capture the wirebonds.

11. The mounting for a semiconductor package in accordance with claim 8 further comprising a plurality of channels formed in the top surface of the leadframe.

12. The mounting for a semiconductor package in accordance with claim 8 wherein the at least one channel is triangular in shape.

13. The mounting for a semiconductor package in accordance with claim 8 wherein the at least one channel is “U” shaped.

14. A mounting for a semiconductor package, comprising:
a leadframe; and
means formed on the leadframe for forming a lock between the leadframe and a mold compound which flows into the means.

15. The mounting for a semiconductor package in accordance with claim 14 further comprising:
a raised area on the leadframe forming a die pad; and
means for allowing a mold compound to get underneath wirebonds on the leadframe and capture the wirebonds.

16. A method for bonding a mold compound to a leadframe, comprising:
forming channels in a leadframe; and
depositing a molding compound on the leadframe wherein the molding compound will flow into the channels for bonding the mold compound to the leadframe.

17. The method of claim 16 further comprising the step of forming triangular shaped channels.

18. The method of claim 17 wherein the step of forming triangular shaped channels further comprises the steps of stamping the leadframe to form the channels.

19. The method of claim 18 further comprising the step of coining the channels to flatten build-up around an opening of the channel caused by stamping the leadframe.

20. The method of claim 16 further comprising the step of forming “U” shaped channels.

21. The method of claim 20 further comprising the step of etching the leadframe to form the “U” shaped channels.

22. The method of claim 16 further comprising the step of forming raised areas on the leadframe to be used for wirebonds wherein the raised areas allow a mold compound to get underneath the wirebonds and capture the wirebonds.

23. The method of claim 16 wherein the step of forming raised areas further comprises the step of etching the leadframe to form the raised areas.
